(19) United States
(12) Patent Application Publication
(10) Pub. No.: US 2025/0162102 A1
(43) Pub. Date: May 22, 2025

(54) WHEEL REPLACING APPARATUS AND WHEEL REPLACING SYSTEM INCLUDING THE SAME

(71) Applicant: Samsung Electronics Co., Ltd., Suwon-si (KR)

(72) Inventors: Jwa Hyeon KIM, Suwon-si (KR); Kyung-Yeol KIM, Suwon-si (KR); Tae-Sung KIM, Suwon-si (KR); Hyun-Tae KIM, Suwon-si (KR); Byung-Hyuck AHN, Suwon-si (KR)

(73) Assignee: Samsung Electronics Co., Ltd., Suwon-si (KR)

(21) Appl. No.: 18/827,041

(22) Filed: Sep. 6, 2024

(30) Foreign Application Priority Data
Nov. 21, 2023 (KR) 10-2023-0162235

(51) Int. Cl. B24B 45/00; B24B 7/22

(52) U.S. Cl. CPC B24B 45/003; B24B 7/228

(57) ABSTRACT

A wheel replacing apparatus includes a partitioning wall including opposite first and second surfaces opposite in a first direction, a motor, a transmission unit, a support extending in a second direction intersecting the first direction, a rotating unit between the support and the transmission unit, an arc-shaped portion connected to the support and having an open inner wall and a shape including a portion of a circle having a central axis extending in a third direction perpendicular to the first and second directions, a roller within the arc-shaped portion, a clamp connector extending from the support in the first direction, and a clamp connected to the clamp connector and having a curved portion. The wheel replacing apparatus is configured to adjust a spacing between the arc-shaped portion and the clamp. The rotating unit is configured to rotate around a rotating unit central axis that extends in the third direction.

### CROSS-REFERENCE TO RELATED APPLICATION

This application claims priority from Korean Patent Application No. 10-2023-0162235 filed on Nov. 21, 2023 in the Korean Intellectual Property Office, and all the benefits accruing therefrom under 35 U.S.C. 119, the contents of which in its entirety are herein incorporated by reference.

### BACKGROUND

### Field

The present inventive concepts relate to wheel replacing apparatuses and wheel replacing systems including the same. More specifically, the present inventive concepts relate to wheel replacing apparatuses that may automatically replace a wheel used during wafer processing and wheel replacing systems including the same.

### Description of Related Art

A wheel may be used in a wafer back grinding process. On one side of the wheel, there may be saw teeth made of a material such as diamond. When the wafer back grinding process is performed repeatedly, the saw teeth of the wheel inevitably wear out. Therefore, it is necessary to replace the wheel periodically.

When an operator replaces the wheel, it may be unsafe for the operator. Furthermore, while the operator is changing the wheel, a loss of manpower may occur. Therefore, research is being conducted to automate a wheel replacement task.

### SUMMARY

Some example embodiments of the present inventive concepts provide a wheel replacing apparatus that may automatically replace the wheel and has improved efficiency.

Some example embodiments of the present inventive concepts provide a wheel replacing system that may automatically replace the wheel and has improved efficiency.

Example embodiments according to the present inventive concepts are not limited to the above-mentioned example embodiments. Other purposes and advantages according to the present inventive concepts that are not mentioned may be understood based on following descriptions, and may be more clearly understood based on embodiments according to the present inventive concepts. Further, it will be easily understood that the purposes and advantages according to the present inventive concepts may be realized using means shown in the claims or combinations thereof.

According to some example embodiments of the present inventive concepts, a wheel replacing apparatus may include a partitioning wall including a first surface and a second surface opposite to each other in a first direction, a motor on the first surface, a transmission unit on the second surface and configured to transmit power of the motor, a support extending in a second direction intersecting the first direction, wherein the support is on the second surface, and the support includes a third surface and a fourth surface opposite to each other in the first direction, a rotating unit between the support and the transmission unit and configured to receive the power from the transmission unit, an arc-shaped portion connected to the support and on the fourth surface of the support, wherein the arc-shaped portion has an open inner wall and has a shape including a portion of a circle having a central axis extending in a third direction perpendicular to a plane defined by the first direction and the second direction, a roller within the arc-shaped portion and having a cylindrical shape, a clamp connector extending from the support in the first direction and disposed on a fourth surface of the support, and a clamp connected to an inner wall of the clamp connector, wherein the clamp has a curved portion, wherein the second surface and the third surface face each other, the arc-shaped portion and the clamp are adjacent to each other in the third direction, the wheel replacing apparatus is configured to adjust a spacing between the arc-shaped portion and the clamp, and the rotating unit is configured to rotate around a rotating unit central axis of the rotating unit, the rotating unit central axis extending in the third direction.

According to some example embodiments of the present inventive concepts, a wheel replacing apparatus may include a partitioning wall including a first surface and a second surface opposite to each other in a first direction, a motor on the first surface, a transmission unit on the second surface and configured to transmit power of the motor, a support extending in a second direction intersecting the first direction and on the second surface, wherein the support has a third surface and a fourth surface opposite to each other in the first direction, a rotating unit between the support and the transmission unit and configured to receive the power from the transmission unit, an arc-shaped portion connected to the support and disposed on the fourth surface of the support, wherein the arc-shaped portion has an open inner wall, and has a shape including a portion of a circle having a central axis extending in a third direction perpendicular to a plane defined by the first direction and the second direction, pulleys within the arc-shaped portion, a belt surrounding the pulleys, a clamp connector extending from the support in the first direction and on the fourth surface of the support, and a clamp connected to an inner wall of the clamp connector and having a curved portion, wherein the second surface and the third surface face each other, the arc-shaped portion and the clamp are adjacent to each other in the third direction, the wheel replacing apparatus is configured to adjust a spacing between the arc-shaped portion and the clamp, the rotating unit is configured to rotate around a rotating unit central axis of the rotating unit, the rotating unit central axis extending in the third direction, and the belt and the pulleys are configured to operate in a timing belt manner.

According to some example embodiments of the present inventive concepts, a wheel replacing system may include a storage unit configured to store therein a wheel for grinding a wafer, a wheel replacing apparatus configured to transport the wheel, a guide rail providing a path along which the wheel replacing apparatus is configured to move, a connection member connecting the guide rail and the wheel replacing apparatus to each other, and a processing unit configured to support the wafer to be ground by the wheel, wherein the wheel replacing apparatus includes a partitioning wall including a first surface and a second surface opposite to each other in a first direction, a motor on the first surface, a transmission unit on the second surface and configured to transmit power of the motor, a support extending in a second direction intersecting the first direction, wherein the support is on the second surface and includes a third surface and a fourth surface opposite to each other in the first direction, a rotating unit between the support and the transmission unit and configured to receive the power from the transmission unit, an arc-shaped portion connected to the support and on the fourth surface of the support, wherein the arc-shaped portion has an open inner wall and has a shape including a portion of a circle having a central axis extending in a third direction perpendicular to a plane defined by the first direction and the second direction, a roller within the arc-shaped portion and having a cylindrical shape, a clamp connector extending from the support in the first direction and on a fourth surface of the support; and a clamp connected to an inner wall of the clamp connector, wherein the clamp has a curved portion, wherein the second surface and the third surface face each other, the arc-shaped portion and the clamp are adjacent to each other in the third direction, the wheel replacing apparatus is configured to adjust a spacing between the arc-shaped portion and the clamp, and the rotating unit is configured to rotate around a rotating unit central axis of the rotating unit, the rotating unit central axis extending in the third direction.

Specific details of some example embodiments are included in the detailed descriptions and drawings.

### BRIEF DESCRIPTION OF THE DRAWINGS

The above and other aspects and features of the present inventive concepts will become more apparent by describing in detail some example embodiments thereof with reference to the attached drawings, in which:

FIG. 1 is a schematic perspective view for illustrating a wheel replacing system according to some example embodiments of the present inventive concepts;

FIG. 2 is a schematic perspective view for illustrating a wheel replacing apparatus according to some example embodiments of the present inventive concepts;

FIG. 3 is a cross-sectional view cut along A-A′ in FIG. 2 according to some example embodiments of the present inventive concepts;

FIG. 4 is a schematic perspective view for illustrating the storage unit in FIG. 1 according to some example embodiments of the present inventive concepts;

FIG. 5 is a schematic perspective view for illustrating a wheel replacing apparatus according to some example embodiments of the present inventive concepts;

FIG. 6 is a cross-sectional view cut along B-B′ in FIG. 5 according to some example embodiments of the present inventive concepts;

FIGS. 7, 8, 9, 10, 11, and 12 are diagrams for illustrating an operation of the wheel replacing apparatus according to some example embodiments of the present inventive concepts.

### DETAILED DESCRIPTION

Hereinafter, some example embodiments of the inventive concepts will be described in detail with reference to the accompanying drawings. The same reference numerals are used for the same components in the drawings, and redundant descriptions thereof are omitted.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, an element that is “on” another element may be above, beneath, or horizontally next to (e.g., horizontally adjacent to) the other element and is not necessarily above an upper side of the other element based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

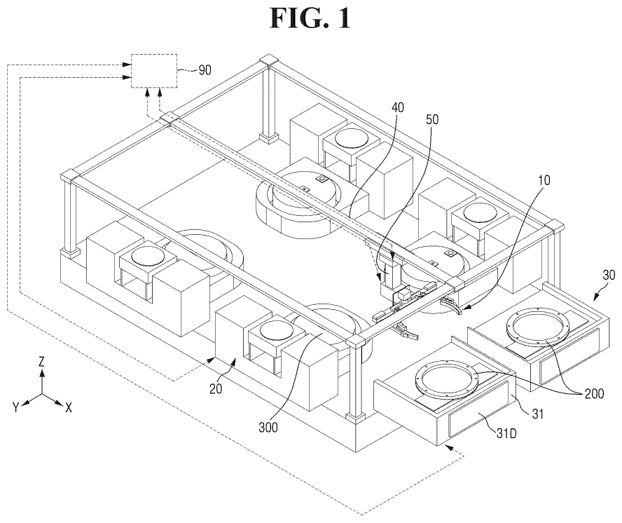

FIG. 1 is a schematic perspective view for illustrating a wheel replacing system according to some example embodiments of the present inventive concepts.

Referring to FIG. 1, the wheel replacing system may include a wheel replacing apparatus 10, a processing unit 20, a storage unit 30, a guide rail 40, and a connection member 50.

The wheel replacing apparatus 10 may grip, transport, or replace a wheel 200.

The wheel replacing apparatus 10 may hold the wheel 200 stored in the storage unit 30. The wheel replacing apparatus 10 may couple the gripped wheel 200 to a disk 400, which will be described later. The disk 400 may be included in the processing unit 20. The wheel replacing apparatus 10 may replace the wheel 200 coupled to the disk 400, whose saw teeth 210 are worn, with a new wheel 200. The wheel 200, coupled to the disk 400, may be used by the processing unit 20 to process (e.g., grind) a wafer (e.g., as part of a back grinding process to prepare wafers for use in semiconductor device manufacture)

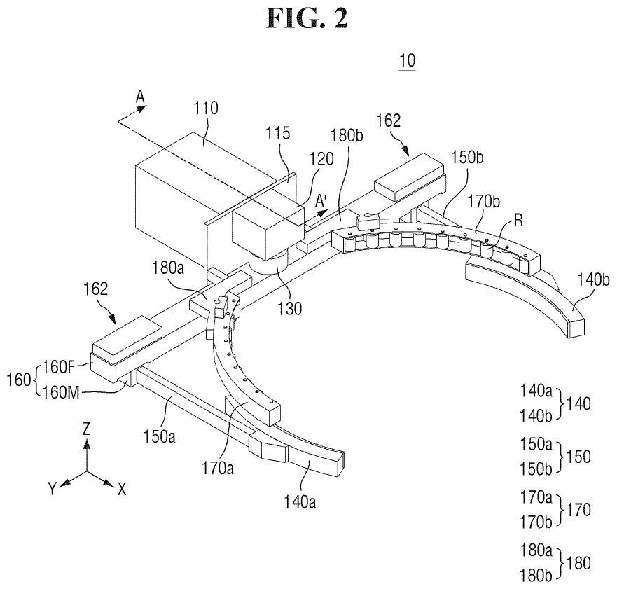

The wheel replacing apparatus 10 may rotate (e.g., pivot around an axis). For example, the wheel replacing apparatus 10 and/or the connection member 50 may include a motor, actuator, servoactuator, or the like mechanically coupled to the wheel replacing apparatus 10 and communicatively coupled to a controller 90 and configured to cause the wheel replacing apparatus 10 to pivot around an axis extending in the third direction Z based on operation of the motor, actuator, servoactuator, or the like under control by the controller 90. In FIG. 2, the wheel replacing apparatus 10 is shown only as being disposed as to face in a first direction X. However, example embodiments of the present inventive concepts are not limited thereto. For example, the wheel replacing apparatus 10 may be disposed to face in a second direction Y.

The processing unit 20 may process (e.g., grind) a wafer. The wafer may be disposed on the processing unit 20, such that the processing unit 20 may support the wafer (e.g., on a surface, pedestal, chuck, or the like). The wafer disposed on the processing unit 20 may be fixed by the processing unit 20. The processing unit 20 may receive energy needed for the wafer fixation, etc. In some example embodiments, the processing unit 20 may use a wheel 200 to perform at least a portion of the processing (e.g., grinding the wafer). For example, the processing unit 20 may support the wafer (e.g., on a surface) and may apply and rotate the wheel 200 (e.g., around a central axis of the wheel 200), for example based on the processing unit 20 having a drive unit 300 that is mechanically coupled to the wheel 200 and configured to rotate the wheel 200 around a wheel central axis 200CP of the wheel 200 to grind a surface of the wafer.

The storage unit 30 may store therein the wheel 200. A new wheel 200 having saw teeth 210 that are not worn may be temporarily stored in the storage unit 30. A wheel 200 having saw teeth 210 that are worn out may be temporarily stored in the storage unit 30. For example, the storage unit 30 may include one or more shelves or the like that are configured to define one or more receiving spaces S to accommodate and store one or more wheels 200.

The storage unit 30 may include a cover 31D that may be opened or closed. The new wheel 200 may be supplied to the storage unit 30 from a position out of the wheel replacing system. Conversely, the wheel 200 that has been consumed may be removed from the storage unit 30 to a position out of the wheel replacing system.

The guide rail 40 may provide a path along which the wheel replacing apparatus 10 may move. The wheel replacing apparatus 10 may move along the guide rail 40. The guide rail 40 may be spaced apart from the wheel replacing apparatus 10 in a third direction Z.

A layout of the guide rail 40 shown in FIG. 1 is merely illustrative, and a specific arrangement of the guide rail 40 is not limited to that shown in FIG. 1.

The connection member 50 may connect the guide rail 40 and the wheel replacing apparatus 10 to each other. The connection member 50 may extend in the third direction Z. For example, the connection member 50 may include a connector that is configured to couple with the guide rail 40, where the connector may include a mover element, which may include one or more sets of motorized wheels, belts, pulleys, or the like which are configured to be driven to cause the connection member 50 to move along the guide rail 40. The connection member 50 may include a driver element, which may include one or more motors, actuators, drivers or the like (e.g., any known electric motor, actuator, servoactuator or the like). The driver element may be mechanically coupled to the mover element to configure the connection member 50 to move along the guide rail 40 and thus to move the wheel replacing apparatus 10 along the guide rail 40. In some example embodiments, the guide rail 40 may include one or more driver elements and one or more mover elements configured to operate to cause the connection member 50 to move along the guide rail 40.

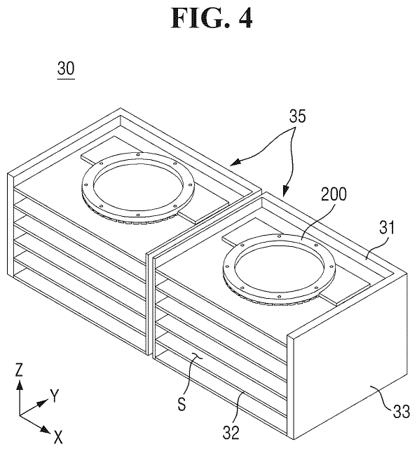

A length of the connection member 50 in the third direction Z may be adjusted. For example, the connection member 50 may include an actuator, motor, or the like (e.g., any known electric motor, actuator, servoactuator or the like) which may be the same or different from the driver element described above and which may be configured to operate to adjust a length of the connection member 50 in the third direction Z. The length of the connection member 50 in the third direction Z may vary. When the length of the connection member 50 in the third direction Z is adjusted, the wheel replacing apparatus 10 may reach a receiving space S (shown in FIG. 4) located at various vertical levels. In other words, the length of the connection member 50 in the third direction Z is adjusted, so that the wheel replacing apparatus 10 may grip the wheel 200 positioned at various vertical levels. Furthermore, the length of the connection member 50 in the third direction Z is adjusted, so that the wheel replacing apparatus 10 may dispose the wheel 200 in the receiving space S located at various vertical levels.

As shown, the wheel replacing system may include one or more controllers 90 which may be communicatively (e.g., electrically) coupled to one or more of the wheel replacing apparatus 10, one or more of the processing units 20, one or more of the storage units 30, the guide rail 40, the connection member 50, any combination thereof, or the like. While FIG. 1 illustrates a single controller 90 that is communicatively coupled to each of the wheel replacing apparatus 10, the processing units 20, the storage units 30, the guide rail 40, and the connection member 50, example embodiments are not limited thereto and in some example embodiments a controller 90 may be communicatively coupled to a limited selection of the wheel replacing apparatus 10, one or more of the processing units 20, one or more of the storage units 30, the guide rail 40, the connection member 50, any combination thereof, or the like. For example, a single controller 90 may be communicatively coupled to the connection member 50 and the wheel replacing apparatus 10 and may not be communicatively coupled to any of the processing units 20 or storage units 30. In some example embodiments, one or more of the wheel replacing apparatus 10, one or more processing units 20, one or more storage units 30, the guide rail 40, the connection member 50, any combination thereof, or the like may include a controller 90 therein and communicatively coupled thereto.

In some example embodiments, a controller 90 is configured to operate one or more communicatively coupled elements (e.g., the wheel replacing apparatus 10, the connection member 50, one or more processing units 20, one or more storage units 30, the guide rail 40 any combination thereof, or the like), for example based on controlling a supply of electric al power thereto. For example, in some example embodiments, the controller 90 is communicatively coupled to the connection member 50 and the wheel replacing apparatus 10 and is configured to control the connection member 50 to adjustably move the connection member 50 (and coupled wheel replacing apparatus 10) along the guide rail 40 and/or adjust the length of the connection member 50 (and thus the vertical level of the wheel replacing apparatus 10) in the Z direction, to control the wheel replacing apparatus 10 to grip and/or release a wheel 200, to engage and/or rotate a disk 400 of the processing unit 20 to align with a gripped wheel 200, any combination thereof, or the like, for example based on controlling a supply of electrical power to one or more motors, actuators, drivers, or the like.

As described herein, any devices, systems, modules, portions, units, controllers, circuits, and/or portions thereof according to any of the example embodiments, and/or any portions thereof (including, without limitation, the wheel replacing apparatus 10, the processing units 20, the storage units 30, the guide rail 40, the connection member 50, the controller 90, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

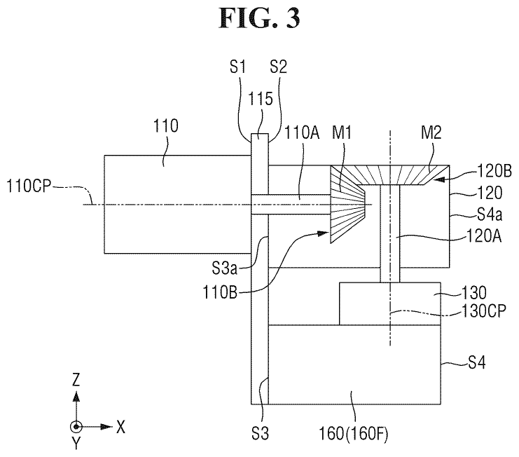

FIG. 2 is a schematic perspective view for illustrating a wheel replacing apparatus according to some example embodiments of the present inventive concepts. FIG. 3 is a cross-sectional view cut along A-A′ in FIG. 2 according to some example embodiments of the present inventive concepts.

Referring to FIGS. 2 and 3, the wheel replacing apparatus 10 includes a motor 110, a partitioning wall 115, a transmission unit 120, a rotating unit 130, a clamp 140a and 140b (which may be referred to collectively as a clamp 140), and a clamp connector 150a and 150b (which may be referred to collectively as a clamp connector 150), a support 160, an arc-shaped portion 170 (e.g., arc-shaped portion 170a and 170b), and a roller R (e.g., a plurality of rollers R).

The motor 110 may extend in the first direction X.

The motor 110 is shown as having a shape of a square pillar. However, example embodiments of the present inventive concepts are not limited thereto.

The motor 110 may be disposed on a first surface S1 of the partitioning wall 115. The motor 110 may overlap the partitioning wall 115 in the first direction X.

The motor 110 may receive power to rotate a motor shaft 110A (e.g., based on operation of a communicatively coupled controller 90). The motor may be any electrical motor, servoactuator, driver, or the like, but example embodiments are not limited thereto.

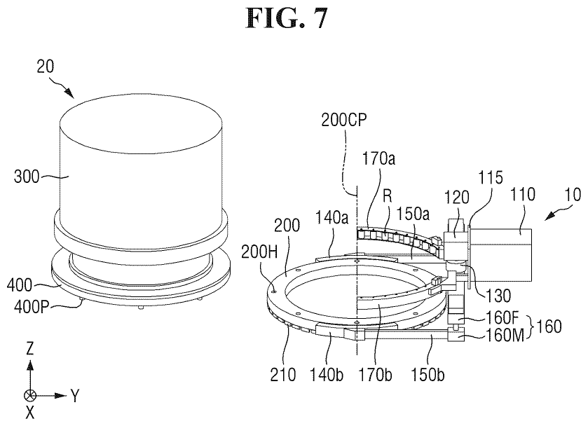

The partitioning wall 115 may include the first surface S1 and a second surface S2 that are opposite to each other in the first direction X, for example such that the first direction X extends perpendicular to one or both of the first surface S1 and/or the second surface S2. The second direction Y may extend perpendicular to the first direction X, and the third direction Z may extend perpendicular to both the first and second directions X and Y. The third direction Z may be understood to extend parallel to the rotating unit central axis 130CP, the wheel central axis 200CP when the wheel 200 is gripped by the clamp 140 as shown for example in FIG. 7, any combination thereof, or the like.

The partitioning wall 115 may be disposed between the motor 110 and the transmission unit 120. The first surface S1 of the partitioning wall 115 may be in contact with the motor 110. The second surface S2 of the partitioning wall 115 may contact one side wall of the transmission unit 120.

The rotating unit 130 may be disposed on the second surface S2 of the partitioning wall 115. The partitioning wall 115 may be spaced apart from the rotating unit 130 in the first direction X.

The support 160 may be disposed on the second surface S2 of the partitioning wall 115. For example, a fixed support 160F may be disposed on the second surface S2 of the partitioning wall 115. The second surface S2 of the partitioning wall 115 may be in contact with one surface of the fixed support 160F.

The partitioning wall 115 is shown as being embodied as a square plate. However, example embodiments of the present inventive concepts are not limited thereto.

The partitioning wall 115 may fix the fixed support 160F in contact with the second surface S2 of the partitioning wall 115. In other words, the fixed support 160F may not move while being in contact with the second surface S2 of the partitioning wall 115.

The transmission unit 120 may extend in the first direction X.

The transmission unit 120 is shown as having a shape of a square pillar. However, example embodiments of the present inventive concepts are not limited thereto.

The transmission unit 120 may include a third surface S3a and a fourth surface S4a that are opposite to each other in the first direction X.

The transmission unit 120 may have a hollow shape.

The transmission unit 120, which may be interchangeably referred to as a transmission device, a drive transmission, or the like, may include a motor shaft 110A, a motor head 110B, a transmission shaft 120A, and a transmission head 120B.

The transmission unit 120 may overlap the partitioning wall 115 in the first direction X.

The motor shaft 110A may extend in the first direction X. The motor shaft 110A may extend through the partitioning wall 115.

The motor shaft 110A may have a cylindrical shape. However, example embodiments of the present inventive concepts are not limited thereto.

At least a portion of the motor shaft 110A may be disposed inside the partitioning wall 115. At least a portion of the motor shaft 110A may be disposed inside the transmission unit 120.

The motor shaft 110A may be connected to a side wall of the motor 110.

The motor shaft 110A may rotate around a motor central axis 110CP extending in the first direction X, based on operation of the motor 110 to rotate the motor shaft 110A.

The motor head 110B may be connected to the motor shaft 110A.

The motor head 110B may have a truncated cone shape. However, embodiments of the present inventive concepts are not limited thereto.

The motor head 110B may be formed integrally with the motor shaft 110A, for example such that the motor head 110B and the motor shaft 110A are separate portions of a single, unitary piece of material. When the motor shaft 110A rotates around the motor central axis 110CP (e.g., based on operation of the motor 110), the motor head 110B may rotate in the same direction as the rotation direction of the motor shaft 110A.

The side wall of the motor head 110B may include a motor thread M1.

One side wall of the transmission unit 120 may be in contact with the partitioning wall 115. More specifically, one side wall of the transmission unit 120 may contact the third surface S3 of the partitioning wall 115.

A lower surface of the transmission unit 120 may be in contact with the rotating unit 130. More specifically, the lower surface of the transmission unit 120 may contact an upper surface of the rotating unit 130.

The transmission shaft 120A may extend in the third direction Z.

The transmission shaft 120A may have a cylindrical shape. However, example embodiments of the present inventive concepts are not limited thereto.

At least a portion of the transmission shaft 120A may be disposed inside the transmission unit 120.

The transmission shaft 120A may be connected to an upper surface of the rotating unit 130.

The transmission shaft 120A may rotate around a rotating unit central axis 130CP extending in the third direction Z.

The transmission head 120B may be connected to the transmission shaft 120A.

The transmission head 120B may have a truncated cone shape. However, example embodiments of the present inventive concepts are not limited thereto.

The transmission head 120B may be formed integrally with the transmission shaft 120A, for example such that the transmission head 120B and the transmission shaft 120A are separate portions of a single, unitary piece of material. When the transmission shaft 120A rotates around the rotating unit central axis 130CP, the transmission head 120B may rotate in the same direction as the rotation direction of the transmission shaft 120A.

A side wall of the transmission head 120B may include a transmission thread M2.

The rotating unit 130 may have a cylindrical shape. However, example embodiments of the present inventive concepts are not limited thereto.

The rotating unit 130 may overlap the partitioning wall 115 in the first direction X.

The rotating unit 130 may be spaced apart from the transmission unit 120 in the third direction Z. More specifically, an upper surface of the rotating unit 130 and a lower surface of the transmission unit 120 may be spaced apart from each other in the third direction Z.

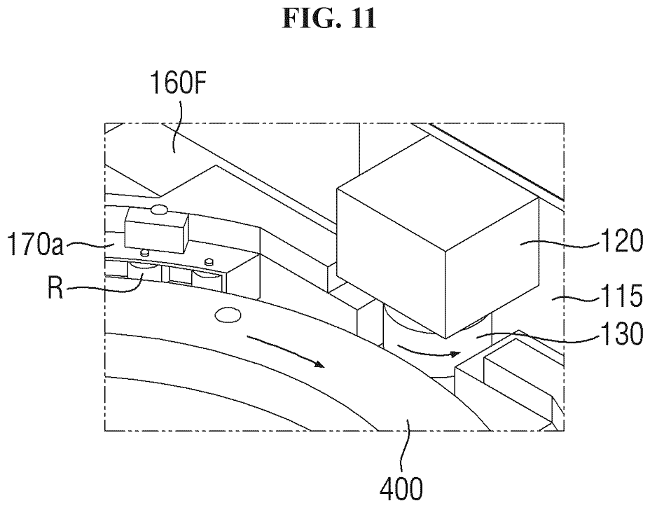

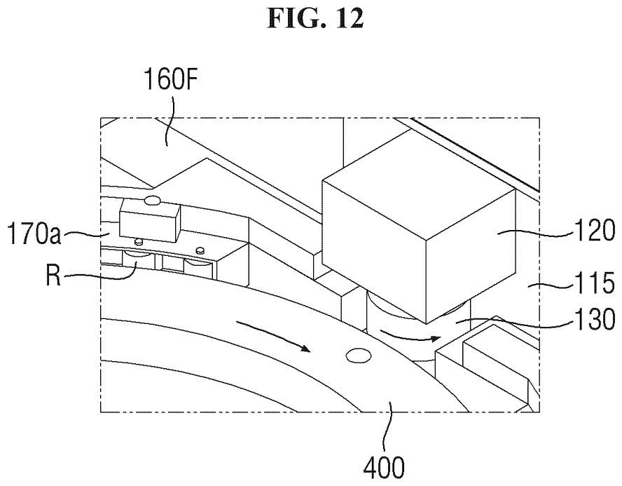

The rotating unit 130 may be in contact with the fixed support 160F. More specifically, a lower surface of the rotating unit 130 and an upper surface of the fixed support 160F may be in contact with each other. The rotating unit 130 may be configured to move (e.g., rotate around the rotating unit central axis 130CP as shown in FIGS. 11-12) in relation to the fixed support 160F, for example based on operation of the motor 110 (e.g., based on control thereof by a controller 90).

The rotating unit 130 may be disposed between the transmission unit 120 and the support 160. More specifically, the rotating unit 130 may be disposed between the transmission unit 120 and the fixed support 160F.

The rotating unit 130 may overlap the transmission unit 120 in the third direction Z. The rotating unit 130 may overlap the support 160 in the third direction Z.

The rotating unit 130 may include, for example, a structure (e.g., a cylindrical structure) that is configured to rotate in relation to the fixed support 160F and around the rotating unit central axis 130CP based on being rotated (e.g., driven) by the transmission shaft 120A. As a result, the motor 110 may be mechanically coupled to the rotating unit 130 through the transmission unit 120, and the wheel replacing apparatus 10 may be configured to operate the motor 110 (e.g., based on operation of the controller 90) to cause the rotating unit 130 to rotate around the rotating unit central axis 130CP in relation to the fixed support 160F.

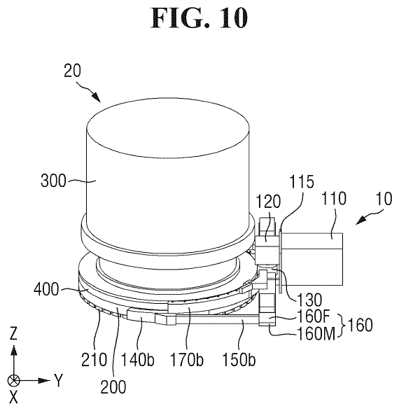

The rotating unit 130 may rotate the disk 400 held by the arc-shaped portion 170 (as shown in FIGS. 10 and 11) based on rotating around the rotating unit central axis 130CP and further based on the disk 400 being at least partially surrounded by and/or being engaged with (e.g., held by) at least the arc-shaped portion 170. More specifically, the disk 400 held by the arc-shaped portion 170 and the rotating unit 130 may be in contact with each other. A frictional force may be generated between the disk 400 and the rotating unit 130. Therefore, as the rotating unit 130 may rotate, the disk 400 may rotate at the same time. For example, the wheel replacing apparatus 10 may be configured to cause the disk 400 to rotate in relation to the wheel replacing apparatus 10 based on causing the rotating unit 130 to rotate in relation to the fixed support 160F based on operation of the motor 110.

In some example embodiments, the rotating unit 130 may rotate counterclockwise (in relation to the fixed support 160F from a plan view in the Z direction) while the disk 400 may rotate clockwise (e.g., as shown in FIGS. 11-12).

In some example embodiments, the rotating unit 130 may rotate clockwise while the disk 400 may rotate counterclockwise.

The motor head 110B and the transmission head 120B may be in contact with each other. More specifically, a sidewall of the motor head 110B and a sidewall of the transmission head 120B may contact each other.

The motor thread M1 of the motor head 110B and the transmission thread M2 of the transmission head 120B may be engaged with each other. When the motor head 110B rotates while the motor thread M1 and the transmission thread M2 are engaged with each other, the transmission head 120B may rotate.

The motor head 110B and the transmission head 120B may be perpendicular to each other. When the motor head 110B and the transmission head 120B are perpendicular to each other, rotation directions thereof may be different from each other. More specifically, the motor head 110B may rotate about the motor central axis 110CP extending in the first direction X, while the transmission head 120B may rotate about the rotating unit central axis 130CP extending in the third direction Z.

The rotating unit 130 may rotate around the rotating unit central axis 130CP based on electrical power being supplied to the motor 110 (e.g., based on operation of the motor 110 in response to receiving electrical power).

More specifically, the motor 110 may receive the electrical power (e.g., based on operation of a communicatively coupled controller 90).

Subsequently, the motor shaft 110A may be rotated under the power supplied to the motor 110 (e.g., the motor shaft 110A may be driven by the motor 110 under control by the controller 90 to rotate). The motor shaft 110A may be mechanically coupled to and/or may be integrated to a drive shaft of the motor 110. The motor shaft 110A may rotate around the motor central axis 110CP extending in the first direction X. As the motor shaft 110A rotates (e.g., based on rotation of the motor shaft 110A), the motor head 110B may rotate in the same direction as the rotation direction of the motor shaft 110A.

Then, the transmission head 120B may rotate while the motor thread M1 and the transmission thread M2 are engaged with each other (e.g., based on rotation of the motor head 110B). The transmission head 120B may rotate around the rotating unit central axis 130CP extending in the third direction Z. As the transmission head 120B rotates, the transmission shaft 120A may rotate in the same direction as the rotation direction of the transmission head 120B.

Subsequently, the rotating unit 130 may rotate around the rotating unit central axis 130CP. More specifically, the transmission shaft 120A and the rotating unit 130 may be formed integrally with each other into one body (e.g., the transmission shaft 120A and the rotating unit 130 may be separate portions of a single, unitary piece of material). Thus, the transmission shaft 120A and the rotating unit 130 may rotate in the same direction. In some example embodiments, the rotating unit 130 may be movably coupled to the fixed support 160F such that the rotating unit 130 is configured to rotate around the rotating unit central axis 130CP while the fixed support 160F remains fixed in place. For example, the rotating unit 130 may be movably coupled to the fixed support 160F via a bearing and shaft extending along the rotating unit central axis 130CP to the fixed support 160F, where at least one of the bearing or the shaft may be fixed to the fixed support 160F, such that the rotating unit 130 may rotate while the fixed support 160F remains fixed in position.

The support 160 may extend in the second direction Y.

The support 160 may include a third surface S3 and a fourth surface S4 that are opposite to each other in the first direction X.

The third surface S3 of the support 160 may contact the second surface S2 of the partitioning wall 115. The third surface S3 of the support 160 may face the second surface S2 of the partitioning wall 115.

The support 160 may include the fixed support 160F and a movable support 160M.

The fixed support 160F may be in contact with the second surface S2 of the partitioning wall 115.

The fixed support 160F may contact the second surface S2 of the partitioning wall 115 and may not move (e.g., may be configured to not move) in the third direction Z.

The movable support 160M may be disposed on each of both opposing ends (e.g., opposite ends) of the fixed support 160F.

The movable support 160M may be disposed under the fixed support 160F. The movable support 160M may overlap with the fixed support 160F in the third direction Z.

The movable support 160M may move in the third direction Z. For example, the wheel replacing apparatus 10 may include one or more drivers 162 (which may include one or more motors, actuators, servoactuators, or the like) mechanically coupled to the movable support 160M and configured to operate (e.g., based on receiving electrical power from a communicatively coupled controller 90 and thus under control by the controller 90) to move in relation to the fixed support 160F.

In some example embodiments, the support 160 may include a protrusion 180a and 180b (which may be collectively referred to as a protrusion 180). The protrusion 180a and 180b may protrude in the third direction Z from an upper surface of the fixed support 160F. The protrusion 180a and 180b may extend along at least a portion of an outer circumference of the arc-shaped portion 170a and 170b. An inner wall of the protrusion 180a and 180b may contact an outer wall of the arc-shaped portion 170a and 170b.

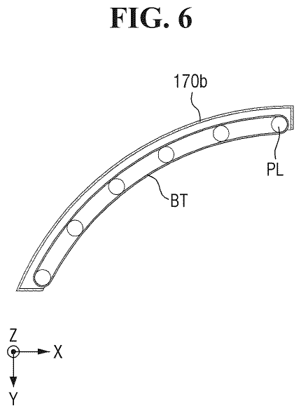

Referring to FIGS. 6-9, which will be described later, the wheel 200 may be held by the clamp 140a and 140b. The wheel 200 may be shaped into a donut with an opened inner area. The wheel 200 may have a wheel central axis 200CP extending in the third direction Z. In the present inventive concepts, an inner side may refer to a portion relatively close to the wheel central axis 200CP. In the present inventive concepts, an outer side may refer to a portion that is relatively distant from the wheel central axis 200CP.

For example, an outer wall of the clamp 140a may contact an inner wall of the clamp connector 150a. In another example, an inner wall of the protrusion 180a may contact an outer wall of the arc-shaped portion 170a. In still another example, the outer wall of the clamp 140b may contact the inner wall of the clamp connector 150b. In still yet another example, the inner wall of the protrusion 180b may contact the outer wall of the arc-shaped portion 170b.

The arc-shaped portion 170 may contact the protrusion 180. More specifically, the outer wall of the arc-shaped portion 170a and the inner wall of the protrusion 180a may contact each other. In some example embodiments, the outer wall of the arc-shaped portion 170b and the inner wall of the protrusion 180b may contact each other.

The arc-shaped portion 170 may have an arc shape. More specifically, the arc-shaped portion 170 may be a portion of a circle whose central axis extends in the third direction Z.

In some example embodiments, a central axis of the arc-shaped portion 170 may be identical (e.g., coaxial) with the wheel central axis 200CP as shown in FIG. 6.

The arc-shaped portion 170 may not include an inner wall. In other words, the inner wall of the arc-shaped portion 170 may be open.

When the inner wall of the arc-shaped portion 170 is opened, the roller R may be observed as shown in FIG. 2.

The arc-shaped portion 170 may have a hollow shape.

In FIG. 2, a central angle of the arc of the arc-shaped portion is shown to be 90 degrees. However, example embodiments of the present inventive concepts are not limited thereto.

The roller R may be disposed inside the arc-shaped portion 170.

A plurality of rollers R may be disposed inside the arc-shaped portion 170. In FIG. 2, nine rollers R are shown to be disposed inside each of the arc-shaped portions 170a and 170b. However, example embodiments of the present inventive concepts are not limited thereto.

The roller R may have a cylindrical shape extending in the third direction Z. However, embodiments of the present inventive concepts are not limited thereto.

The disk 400 rotated by the rotating unit 130 may be rotated smoothly along a side wall of the roller R. For example, the wheel replacing apparatus 10 may be configured to cause a disk 400 to rotate (e.g., around wheel central axis 200CP) based on causing the rotating unit 130 to rotate in engagement with an outer surface of the disk 400 (e.g., while the disk 400 is at least partially surrounded and/or engaged with the arc-shaped portion 170 and the rotating unit 130) such that the disk 400 is rotated to move along a side wall of one or more rollers R (e.g., in engagement with an outer surface of the one or more rollers R).

The clamp connector 150 may extend in the first direction X.

The clamp connector 150 may extend from the support 160 in the first direction X. More specifically, the clamp connector 150 may extend from the movable support 160M in the first direction X.

At least a portion of an upper surface of the clamp connector 150 may contact at least a portion of a lower surface of the movable support 160M.

The clamp connector 150 may move in the second direction Y (e.g., based on operation of the one or more drivers 162). A spacing between the clamp connector 150a and the clamp connector 150b may be adjusted. Restated, the wheel replacing apparatus 10 may be configured to cause a spacing between the clamp connector 150a and the clamp connector 150b to be adjusted, for example based on operation of one or more drivers 162 (e.g., under control by one or more controllers 90) which may be mechanically coupled to at least one of the clamp connector 150a or the clamp connector 150b.

The clamp 140 may be in contact with the clamp connector 150. An outer wall of the clamp 140 may contact an inner wall of the clamp connector 150.

The clamp 140 may extend in the first direction X.

The clamp 140 may have a curved shape. The clamp 140 may include a portion having a certain curvature.

The wheel 200 including the same curvature as the curvature of the clamp 140, may be held by the clamp 140. In other words, when there is an area where the curvature of the inner wall of the clamp 140 and the curvature of the wheel 200 are equal to each other, the wheel 200 may be held by the clamp 140.

The clamp 140 (e.g., one or both of the clamp 140a and the clamp 140b) may move in the second direction Y. A spacing between the clamp 140a and the clamp 140b spaced apart from each other in the second direction Y may be adjusted. Restated, the wheel replacing apparatus 10 may be configured to cause a spacing between the clamp 140a and the clamp 140b to be adjusted, for example based on operation of one or more drivers 162 (e.g., under control by one or more controllers 90) which may be mechanically coupled to at least one of the clamp 140a or the clamp 140b, for example via the clamp connector 150a and/or the clamp connector 150b).

When the spacing between the clamp connector 150a and the clamp connector 150b is deceased (e.g., based on operation of the one or more drivers 162), the wheel 200 may be gripped. When the spacing between the clamp 140a and the clamp 140b is decreased, the wheel 200 may be gripped.

More specifically, when the spacing between the clamp connector 150a and the clamp connector 150b is increased (e.g., based on operation of the one or more drivers 162), the wheel 200 may be disposed between the clamp connector 150a and the clamp connector 150b. While the wheel 200 is disposed between the clamp connector 150a and the clamp connector 150b, the spacing between the clamp connector 150a and the clamp connector 150b may be decreased. Thus, the clamp 140a and the clamp 140b spaced apart from each other in the second direction Y may contact the wheel 200. Therefore, the wheel 200 may be held by the clamp 140a and the clamp 140b.

When the spacing between the clamp connector 150a and the clamp connector 150b is increased, the wheel 200 may be released therefrom.

More specifically, when the spacing between the clamp connector 150a and the clamp connector 150b increases, the spacing between the clamp 140a and the clamp 140b may increase. When the spacing between the clamp 140a and the clamp 140 increases, the clamps 140a and 140b may not contact the wheel 200. Accordingly, the wheel 200 may be removed from the clamps 140a and 140b.

FIG. 4 is a schematic perspective view for illustrating the storage unit 30 in FIG. 1 according to some example embodiments of the present inventive concepts.

Referring to FIG. 4, the storage unit 30 may include a storage shelf 35. Each storage shelf 35 may include a main wall 31, a horizontal wall 32, and a vertical wall 33.

The main wall 31 may be perpendicular to the first direction X. More specifically, the main wall 31 may extend along a Y-Z plane.

The vertical wall 33 may be perpendicular to the second direction Y. More specifically, the vertical wall 33 may extend along a X-Z plane.

Neighboring vertical walls 33 may be spaced apart from each other in the second direction Y.

The horizontal wall 32 may be perpendicular to the third direction Z. More specifically, the horizontal wall 32 may extend along an X-Y plane.

Neighboring horizontal walls 32 may be spaced apart from each other in the third direction Z.

The main wall 31 and the vertical wall 33 may be in contact with each other. More specifically, the vertical wall 33 may extend from one surface of the main wall 31 in the first direction X.

The main wall 31 and the horizontal wall 32 may be in contact with each other. More specifically, the horizontal wall 32 may extend from one surface of the main wall 31 in the first direction X.

The horizontal wall 32 may contact the vertical wall 33. More specifically, the horizontal wall 32 may extend from one surface of the vertical wall 33 in the second direction Y.

The horizontal wall 32 may be disposed between the vertical walls 33 spaced apart from each other in the second direction Y.

The receiving space S may be defined by the main wall 31, the horizontal wall 32, and the vertical wall 33. More specifically, the receiving space S may be defined by one main wall 31, two horizontal walls 32, and two vertical walls 33.

The wheel 200 may be disposed in the receiving space S. The wheel 200 may be disposed on the uppermost horizontal wall 32.

In FIG. 4, the storage unit 30 is shown as including two storage shelves 35. However, example embodiments of the present inventive concepts are not limited thereto. In order to illustrate the storage unit 30, the two storage shelves 35 are shown by way of example. The number of storage shelves 35 included in the storage unit 30 may be one or three or more.

Each storage shelf 35 is shown as including six horizontal walls 32. However, example embodiments of the present inventive concepts are not limited thereto.

Each storage shelf 35 is shown as including five receiving spaces. However, example embodiments of the present inventive concepts are not limited thereto.

The wheel replacing apparatus 10 may hold the new wheel 200 disposed in the receiving space S or on the uppermost horizontal wall 32. More specifically, when the spacing between the clamp 140a and the clamp 140b spaced apart from each other in the second direction Y is decreased while at least a portion of the clamp 140 is inserted into a receiving space S or on the uppermost horizontal wall 32 so as to at least partially surround a new wheel 200 in the receiving space S or on the uppermost horizontal wall 32 in the X-Y plane, the new wheel 200 disposed in the receiving space S or on the uppermost horizontal wall 32 may be gripped.

The wheel replacing apparatus 10 may dispose the worn wheel 200 in the receiving space S or on the uppermost horizontal wall 32. More specifically, when the spacing between the clamp 140a and the clamp 140b which are spaced apart from each other in the second direction Y increases, a wheel 200 having saw teeth that are worn out and which is gripped by the wheel replacing apparatus 10 may be disposed in the receiving space S or on the uppermost horizontal wall 32.

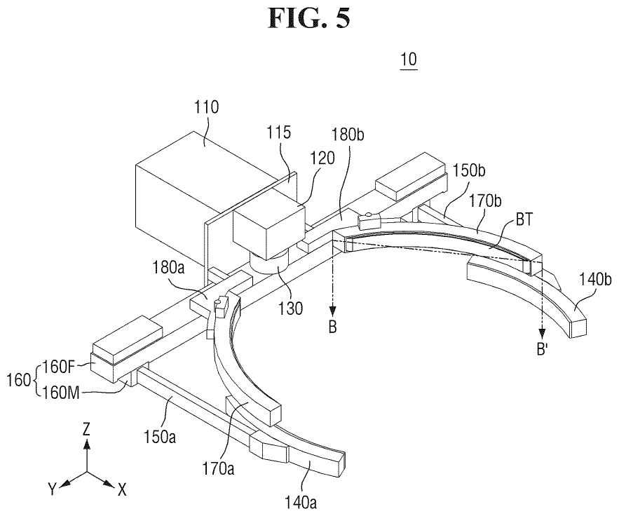

FIG. 5 is a schematic perspective view for illustrating a wheel replacing apparatus according to some example embodiments of the present inventive concepts. FIG. 6 is a cross-sectional view cut along B-B′ in FIG. 5 according to some example embodiments of the present inventive concepts. For convenience of description, following description focuses on differences thereof from FIG. 2.

Referring to FIG. 5 and FIG. 6, the wheel replacing apparatus 10 may include a belt BT and a pulley PL.

The pulley PL may be disposed within the arc-shaped portion 170a or 170b. More specifically, the pulley PL may be disposed between an upper surface of the arc-shaped portion 170a and a lower surface of the arc-shaped portion 170a. Furthermore, the pulley PL may be disposed between an upper surface of the arc-shaped portion 170b and a lower surface of the arc-shaped portion 170b.

The pulley PL may have a cylindrical shape.

The pulley PL may contact the belt BT. A frictional force may be generated between the pulley PL and the belt BT. Therefore, when the belt BT rotates, the pulley PL may rotate simultaneously.

It is shown in FIG. 6 that there are six pulleys PL in the arc-shaped portion 170b and it will be understood that there may similarly be six pulleys PL in the arc-shaped portion 170a. However, example embodiments of the present inventive concepts are not limited thereto. For example, there may be two pulleys PL in each of the arc-shaped portion 170a or 170b.

The belt BT may surround at least a portion of a side surface of the pulley PL.

When a spacing between the arc-shaped portion 170a and the arc-shaped portion 170b spaced apart from each other in the second direction Y is decreased (e.g., based on operation of the wheel replacing apparatus 10) such that the disk 400 is gripped, the belt BT and the disk 400 may contact each other. The belt BT may be deformed in a corresponding manner to a shape of a side wall of the disk 400. Therefore, when the belt BT is used, the disk 400 may rotate even when the side wall of the disk 400 is not smooth.

The pulley PL and the belt BT may operate in a timing belt manner. More specifically, a rotation degree and a rotation time of each of the pulley PL and the belt BT may be controlled. Therefore, when positions of an inserted portion 400P and a wheel hole 200H do not coincide with each other, the pulley PL and the belt BT may be rotated so that the positions of the inserted portion 400P and the wheel hole 200H coincide with each other (see FIGS. 11 and 12).

FIGS. 7, 8, 9, 10, 11, and 12 are diagrams for illustrating an operation of the wheel replacing apparatus 10 according to some example embodiments of the present inventive concepts.

Referring to FIG. 7, the wheel replacing apparatus 10, the wheel 200, a drive unit 300, and the disk 400 may be provided. The disk 400 may be included in a processing unit 20 for processing a wafer.

The wheel replacing apparatus 10 may hold the wheel 200 disposed in the storage unit 30. Subsequently, the wheel replacing apparatus 10 holding the wheel 200 may rotate to face in the second direction Y, for example based on operation of a motor, driving element, or the like (e.g., based on operation of motor 110 under control by a controller 90, based on operation of a driver element of the connection member 50 under control by a controller 90, any combination thereof, or the like). Furthermore, the wheel replacing apparatus 10 holding the wheel 200 may move onto the processing unit 20, for example based on operation of motor 110 under control by a controller 90, based on operation of a driver element of the connection member 50 under control by a controller 90, any combination thereof, or the like.

As shown, a processing unit 20 may include a drive unit 300 in addition to a disk 400. The drive unit 300 may include a motor, driver or the like (e.g., any electrical motor, servoactuator, or the like). The drive unit 300 may extend in the third direction Z.

The drive unit 300 may rotate around a drive unit central axis extending in the third direction Z.

The disk 400 may be disposed under the drive unit 300.

The disk 400 and the drive unit 300 may contact each other. A vertical level of the disk 400 in the third direction Z may be fixed by the drive unit 300. The disk 400 may rotate around the drive unit 300 central axis. The drive unit 300 may be mechanically coupled to the disk 400. The processing unit 20 may be configured to cause the drive unit 300 to induce rotation of the disk 400 around the drive unit central axis (e.g., based on being controlled by a controller 90) to cause a wheel 200 gripped by the disk 400 to rotate, where such a rotating wheel 200 having saw teeth 210 may be used to process a wafer supported by the processing unit 20 (e.g., to grind a surface of the wafer).

An upper surface of the wheel 200 may have the wheel hole 200H recessed in the third direction Z in the upper surface of the wheel 200.

A lower surface of the disk 400 may include the inserted portion 400P that protrudes in the third direction Z from the lower surface of the disk 400.

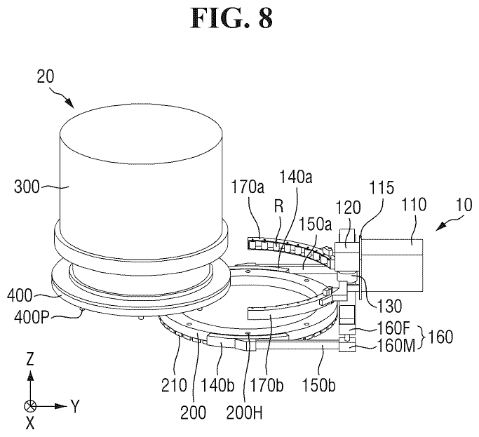

Referring to FIG. 8, the wheel replacing apparatus 10 holding the wheel 200 may move in the second direction Y, for example based on operation of motor 110 under control by a controller 90, based on operation of a driver element of the connection member 50 under control by a controller 90, any combination thereof, or the like. The spacing between the wheel replacing apparatus 10 holding the wheel 200 and the drive unit 300 may be decreased, for example based on operation of motor 110 under control by a controller 90, based on operation of a driver element of the connection member 50 under control by a controller 90, any combination thereof, or the like. In some example embodiments, the spacing between the wheel replacing apparatus 10 holding the wheel 200 and the disk 400 may be decreased, for example based on operation of the motor 110.

The wheel 200 and the disk 400 may be caused to partially overlap each other in the third direction Z based on movement of at least the wheel replacing apparatus 10 in relation to the processing unit 20.

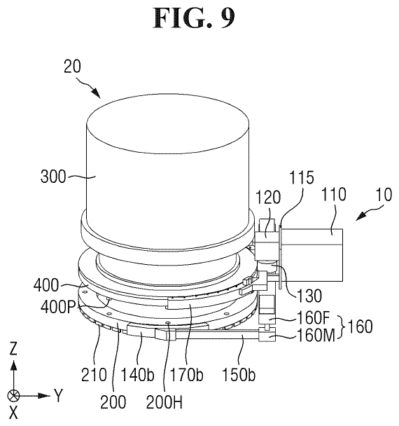

Referring to FIG. 9, the wheel replacing apparatus 10 holding the wheel 200 may move further in the second direction Y, for example based on operation of motor 110 under control by a controller 90, based on operation of a driver element of the connection member 50 under control by a controller 90, any combination thereof, or the like. The spacing between the wheel replacing apparatus 10 holding the wheel 200 and the drive unit 300 may be decreased for example based on operation of motor 110 under control by a controller 90, based on operation of a driver element of the connection member 50 under control by a controller 90, any combination thereof, or the like. In some example embodiments, the spacing between the wheel replacing apparatus 10 holding the wheel 200 and the disk 400 may be decreased, for example based on operation of motor 110 under control by a controller 90, based on operation of a driver element of the connection member 50 under control by a controller 90, any combination thereof, or the like.

The wheel 200 and the disk 400 may entirely overlap each other in the third direction Z based on movement of at least the wheel replacing apparatus 10 in relation to the processing unit 20.

The disk 400 may be at least partially surrounded (e.g., in the X-Y plane) with the arc-shaped portion 170 and the rotating unit 130.

Referring to FIG. 10, the movable support 160M may rise up in the third direction Z in relation to the fixed support 160F, for example based on operation of one or more drivers 162.

When the movable support 160M rises upwardly, the clamp connector 150 and the clamp 140 may rise upwardly simultaneously. Furthermore, the wheel 200 held by the clamp 140 may rise upwardly.

As the wheel 200 rises upwardly, the disk 400 and the wheel 200 may contact each other. More specifically, the lower surface of the disk 400 and the upper surface of the wheel 200 may be in contact with each other.

When the wheel 200 rises upwardly, the inserted portion 400P may be inserted into the wheel hole 200H. The disk 400 may include a connector configured to engage the wheel 200 based on the inserted portion 400P being inserted into the wheel hole 200H to cause the disk 400 to grip the wheel 200 and hold the wheel 200 in contact (e.g., mechanically coupled) with the disk 400.

Although not shown, when the position of the inserted portion 400P does not coincide with (e.g., overlap in the Z direction) the position of the wheel hole 200H, the disk 400 may be rotated by the rotating unit 130 in relation to the wheel 200 (e.g., based on the wheel replacing apparatus 10 causing the rotating unit 130 to rotate based on operation of the motor 110). The disk 400 may rotate until the position of the inserted portion 400P coincides with the position of the wheel hole 200H. In some example embodiments, the wheel replacing apparatus 10 may include a sensor (e.g., an image sensor, camera, or the like configured to capture image data) which may be communicatively coupled to a controller 90, and the coinciding of the inserted portion 400P with the position of the wheel hole 200H may be determined (e.g., by controller 90) based on processing sensor data generated by a sensor (e.g., image data captured by the image sensor showing the relative positions of the inserted portion 400P and the wheel hole 200H), such that the controller 90 may cause the rotating unit 130 to rotate to cause the disk 400 to rotate in relation to the wheel 200 and may stop and/or adjust such rotation of the rotating unit 130 to cause the inserted portion 400P to coincide with the position of the wheel hole 200H).

In some example embodiments, the rotation of the rotating unit 130 to cause rotation of the disk 400 may be manually controlled based on operator interaction with a user interface (e.g., a button and/or lever interface device) to enable manual observation of the relative alignment of the inserted portion 400P and the wheel hole 200H, such that the rotation of the rotating unit 130 may be manually stopped and/or adjusted based on such manual control (e.g., based on the manual observation) to cause to cause the inserted portion 400P to coincide with the position of the wheel hole 200H.

Referring to FIG. 11 and FIG. 12, it is shown that the disk 400 and the rotating unit 130 rotate, for example based on operation of the motor 110, until the position of the inserted portion 400P coincides with the position of the wheel hole 200H. In FIG. 11 and FIG. 12, the drive unit 300 is omitted for convenience of illustration.

In FIG. 11 and FIG. 12, it is shown only that the disk 400 rotates clockwise and the rotating unit 130 rotates counterclockwise. However, example embodiments of the present inventive concepts are not limited thereto. That is, the disk 400 may rotate counterclockwise while the rotating unit 130 may rotate clockwise.

Subsequently, the wheel replacing apparatus 10 and the wheel 200 may be removed from each other, for example based on operation of the motor 110 and/or one or more drivers 162. Subsequently, when the drive unit 300 rotates (e.g., based on operation of the processing unit 20 under control by a controller 90), the disk 400 mechanically coupled thereto may rotate. When the disk 400 rotates, the wheel 200 gripped by the disk 400 may rotate. Subsequently, the wafer disposed under the wheel 200 (e.g., supported by the processing unit 20) may be ground by the saw teeth 210 of the wheel 200.

Typically, replacing the used wheel 200 with the new wheel 200 takes a lot of time. The operator carries the new wheel 200, removes the wheel 200 having the worn saw teeth from the disk 400, joins the new wheel 200 to the disk 400, and transports the wheel 200 having the worn saw teeth.

According to the present inventive concepts, the new wheel 200 may be transferred from the storage unit 30 to the processing unit 20. Furthermore, after gripping the worn wheel 200 with the clamp 140, the worn wheel 200 may be removed from the disk 400 of the processing unit 20. Furthermore, after gripping the new wheel 200 with the clamp 140, the new wheel 200 may be coupled to the disk 400 of the processing unit 20. Furthermore, the worn wheel 200 may be transported from the processing unit 20 to the storage unit 30. Therefore, since no operator is required to replace the wheel 200 (e.g., to manually manipulate, handle, and/or carry the wheel 200), the safety of the operator may be improved, maximized, or guaranteed. Furthermore, since the replacement of the wheel 200 may be automated, the efficiency of the back grinding process may be improved.

Although some example embodiments of the present inventive concepts have been described with reference to the accompanying drawings, the present inventive concepts are not limited to the above example embodiments, but may be implemented in various different forms. A person skilled in the art may appreciate that the present inventive concepts may be practiced in other concrete forms without changing the technical spirit or essential characteristics of the present inventive concepts. Therefore, it should be appreciated that the example embodiments as described above are not restrictive but illustrative in all respects.

In concluding the detailed description, those skilled in the art will appreciate that many variations and modifications may be made to some example embodiments without substantially departing from the principles of the present inventive concepts. Therefore, the example embodiments of the inventive concepts described above are used in a generic and descriptive sense only and not for purposes of limitation.

What is claimed is:

1. A wheel replacing apparatus, comprising:
a partitioning wall including a first surface and a second surface opposite to each other in a first direction;
a motor on the first surface;
a transmission unit on the second surface, the transmission unit configured to transmit power of the motor;
a support extending in a second direction intersecting the first direction, wherein the support is on the second surface, and the support includes a third surface and a fourth surface opposite to each other in the first direction;
a rotating unit between the support and the transmission unit, the rotating unit configured to receive the power from the transmission unit;
an arc-shaped portion connected to the support, wherein the arc-shaped portion is on the fourth surface of the support, wherein the arc-shaped portion has an open inner wall, and wherein the arc-shaped portion has a shape including a portion of a circle having a central axis extending in a third direction perpendicular to a plane defined by the first direction and the second direction;
a roller within the arc-shaped portion, the roller having a cylindrical shape;
a clamp connector extending from the support in the first direction, wherein the clamp connector is on the fourth surface of the support; and
a clamp connected to an inner wall of the clamp connector, wherein the clamp has a curved portion,
wherein the second surface and the third surface face each other,
wherein the arc-shaped portion and the clamp are adjacent to each other in the third direction,
wherein the wheel replacing apparatus is configured to adjust a spacing between the arc-shaped portion and the clamp,
wherein the rotating unit is configured to rotate around a rotating unit central axis of the rotating unit, the rotating unit central axis extending in the third direction.

2. The wheel replacing apparatus of claim 1, wherein the support includes:
a fixed support connected to the second surface, wherein the fixed support is configured to not move in the third direction, and
a movable support at least partially overlapping the fixed support in the third direction, wherein the movable support is configured to move in the third direction.

3. The wheel replacing apparatus of claim 2, wherein
the clamp connector is connected to the movable support, and
the clamp connector is configured to move in the third direction based on the movable support moving in the third direction.

4. The wheel replacing apparatus of claim 1, further comprising a disk surrounded with the arc-shaped portion and the rotating unit,
wherein the wheel replacing apparatus is configured to cause the disk to rotate about a disk central axis extending in the third direction based on the rotating unit rotating about the rotating unit central axis.

5. The wheel replacing apparatus of claim 4, wherein the roller is configured to rotate about a roller central axis extending in the third direction based on the disk rotating about the disk central axis.

6. The wheel replacing apparatus of claim 4, wherein the disk includes an inserted portion protruding from one surface of the disk in the third direction.

7. The wheel replacing apparatus of claim 6, wherein
the clamp is configured to grip a wheel,
the wheel has a wheel hole recessed from one surface of the wheel in the third direction, and
the inserted portion is configured to be inserted into the wheel hole.

8. The wheel replacing apparatus of claim 1, wherein
the clamp is configured to move in the second direction, and
the clamp is configured to grip a portion of a wheel having a curvature equal to a curvature of the curved portion of the clamp.

9. A wheel replacing apparatus, comprising:
a partitioning wall including a first surface and a second surface opposite to each other in a first direction;
a motor on the first surface;
a transmission unit on the second surface, the transmission unit configured to transmit power of the motor;
a support extending in a second direction intersecting the first direction, wherein the support is on the second surface, wherein the support has a third surface and a fourth surface opposite to each other in the first direction;
a rotating unit between the support and the transmission unit, the rotating unit configured to receive the power from the transmission unit;
an arc-shaped portion connected to the support, wherein the arc-shaped portion is on the fourth surface of the support, wherein the arc-shaped portion has an open inner wall, and wherein the arc-shaped portion has a shape including a portion of a circle having a central axis extending in a third direction perpendicular to a plane defined by the first direction and the second direction;
pulleys within the arc-shaped portion;
a belt surrounding the pulleys;
a clamp connector extending from the support in the first direction, wherein the clamp connector is on the fourth surface of the support; and
a clamp connected to an inner wall of the clamp connector, the clamp having a curved portion,
wherein the second surface and the third surface face each other,
wherein the arc-shaped portion and the clamp are adjacent to each other in the third direction,
wherein the wheel replacing apparatus is configured to adjust a spacing between the arc-shaped portion and the clamp,
wherein the rotating unit is configured to rotate around a rotating unit central axis of the rotating unit, the rotating unit central axis extending in the third direction,
wherein the belt and the pulleys are configured to operate in a timing belt manner.

10. The wheel replacing apparatus of claim 9, wherein the support includes:
a fixed support connected to the second surface, wherein the fixed support is configured to not move in the third direction, and
a movable support at least partially overlapping the fixed support in the third direction, wherein the movable support is configured to move in the third direction.

11. The wheel replacing apparatus of claim 10, wherein
the clamp connector is connected to the movable support, and
the clamp connector is configured to move in the third direction based on the movable support moving in the third direction.

12. The wheel replacing apparatus of claim 9, further comprising a disk surrounded with the arc-shaped portion and the rotating unit,
wherein the wheel replacing apparatus is configured to cause the disk to rotate about a disk central axis extending in the third direction based on the rotating unit rotating about the rotating unit central axis.

13. The wheel replacing apparatus of claim 12, wherein the belt is configured to rotate about a belt central axis extending in the third direction based on the disk rotating about the disk central axis.

14. The wheel replacing apparatus of claim 12, wherein the disk includes an inserted portion protruding from one surface of the disk in the third direction.

15. The wheel replacing apparatus of claim 14, wherein
the clamp is configured to grip a wheel,
the wheel has a wheel hole recessed from one surface of the wheel in the third direction, and
the inserted portion is configured to be inserted into the wheel hole.

16. The wheel replacing apparatus of claim 9, wherein
the clamp is configured to move in the second direction, and
the clamp is configured to grip a portion of the wheel having a curvature equal to a curvature of the curved portion of the clamp.

17. A wheel replacing system, comprising:
a storage unit configured to store therein a wheel for grinding a wafer;
a wheel replacing apparatus configured to transport the wheel;
a guide rail providing a path along which the wheel replacing apparatus is configured to move;
a connection member connecting the guide rail and the wheel replacing apparatus to each other; and
a processing unit configured to support the wafer to be ground by the wheel,
wherein the wheel replacing apparatus includes
a partitioning wall including a first surface and a second surface opposite to each other in a first direction,
a motor on the first surface,
a transmission unit on the second surface, the transmission unit configured to transmit power of the motor,
a support extending in a second direction intersecting the first direction, wherein the support is on the second surface, and the support includes a third surface and a fourth surface opposite to each other in the first direction,
a rotating unit between the support and the transmission unit, the rotating unit configured to receive the power from the transmission unit,
an arc-shaped portion connected to the support, wherein the arc-shaped portion is on the fourth surface of the support, wherein the arc-shaped portion has an open inner wall, and wherein the arc-shaped portion has a shape including a portion of a circle having a central axis extending in a third direction perpendicular to a plane defined by the first direction and the second direction,
a roller within the arc-shaped portion, the roller having a cylindrical shape,
a clamp connector extending from the support in the first direction, wherein the clamp connector is on the fourth surface of the support, and
a clamp connected to an inner wall of the clamp connector, wherein the clamp has a curved portion,
wherein the second surface and the third surface face each other,
wherein the arc-shaped portion and the clamp are adjacent to each other in the third direction,
wherein the wheel replacing apparatus is configured to adjust a spacing between the arc-shaped portion and the clamp,
wherein the rotating unit is configured to rotate around a rotating unit central axis of the rotating unit, the rotating unit central axis extending in the third direction.

18. The wheel replacing system of claim 17, wherein the support includes:
a fixed support connected to the second surface, wherein the fixed support is configured to not move in the third direction, and
a movable support at least partially overlapping the fixed support in the third direction, wherein the movable support is configured to move in the third direction.

19. The wheel replacing system of claim 17, wherein
the processing unit further includes a disk,
the wheel replacing apparatus is configured to cause the disk to be at least partially surrounded with the arc-shaped portion and the rotating unit, and
when the wheel replacing apparatus is configured to cause the rotating unit to rotate about the rotating unit central axis while the disk is at least partially surrounded with the arc-shaped portion and the rotating unit to cause the disk to rotate about a disk central axis, the disk central axis extending in the third direction.

20. The wheel replacing system of claim 17, wherein
the clamp is configured to move in the second direction, and
wherein the clamp is configured to grip a portion of the wheel having a curvature equal to a curvature of the curved portion of the clamp.
